(19) United States
(12) Patent Application Publication
(10) Pub. No.: US 2019/0198834 A1
(43) Pub. Date: Jun. 27, 2019

(54) TELECOMMUNICATIONS EQUIPMENT CABINETS INCLUDING ISOLATED AND REMOVABLE BATTERY BOX ASSEMBLIES

(71) Applicant: VERTIV ENERGY SYSTEMS, INC., Lombard, IL (US)

(72) Inventors: Jerome A. MALONEY, Lombard, IL (US); Peter M. SPRAGUE, Lombard, IL (US)

(21) Appl. No.: 15/943,189

(22) Filed: Apr. 2, 2018

Related U.S. Application Data
(60) Provisional application No. 62/609,099, filed on Dec. 21, 2017.

(51) Int. Cl. H01M 2/12; H05K 7/18; H05K 7/14

(52) U.S. Cl. CPC H01M 2/12; H05K 7/1492; H05K 7/186

(57) ABSTRACT

Example telecommunications equipment cabinets include a cabinet housing, and at least one equipment chamber defined within the cabinet housing. The equipment chamber has one or more electrical components disposed therein. The telecommunications equipment cabinet also includes a battery box removably positioned in the cabinet housing. The battery box includes at least one battery, and the battery box is isolated from the equipment chamber to inhibit hydrogen gas from escaping the battery box into the at least one equipment chamber. Associated methods of exchanging components in a telecommunications equipment cabinet are also disclosed.

### CROSS-REFERENCE TO RELATED APPLICATION

This application claims the benefit and priority of U.S. Provisional Application No. 62/609,099, filed on Dec. 21, 2017. The entire disclosure of the above application is incorporated herein by reference.

### FIELD

The present disclosure relates to telecommunications equipment cabinets including isolated and removable battery box assemblies.

### BACKGROUND

This section provides background information related to the present disclosure which is not necessarily prior art.

In telecommunications equipment cabinets, batteries can release hydrogen gas during operation. A fan/filter cooling system is often used to allow hydrogen gas to escape the cabinet through abundant open area ventilation. However, abundant open area ventilation increases the risk of corrosion for significant electrical components stored inside the cabinet. Further, a fan/filter cooling system may not be sufficient to meet thermal requirements of electrical components intended for use within the cabinet, especially in warm climate areas.

In some cases, a separate battery base cabinet may be used in combination with an equipment only cabinet. The equipment only cabinet may be installed on top of the battery base cabinet, or the two cabinets can be deployed side by side. The equipment only cabinet can utilize a cooling system (e.g., air conditioner, heat exchanger, etc.) sufficient to meet thermal requirements of the equipment, without needing to account for hydrogen outgassing because the hydrogen outgassing would be contained within the battery base cabinet. However, this approach necessitates two separate cabinets, which requires more deployment space than may be desired and does not allow for equipment expansion without introducing additional enclosure(s).

### SUMMARY

This section provides a general summary of the disclosure, and is not a comprehensive disclosure of its full scope or all of its features.

According to one aspect of the present disclosure, a telecommunications equipment cabinet includes a cabinet housing, and at least one equipment chamber defined within the cabinet housing. The equipment chamber has one or more electrical components disposed therein. The telecommunications equipment cabinet also includes a battery box removably positioned in the cabinet housing. The battery box includes at least one battery, and the battery box is isolated from the equipment chamber to inhibit hydrogen gas from escaping the battery box into the at least one equipment chamber.

According to another aspect of the present disclosure, a telecommunications equipment cabinet includes a cabinet housing having multiple vents, and at least one equipment chamber defined within the cabinet housing. The at least one equipment chamber has one or more electrical components disposed therein. The telecommunications equipment cabinet also includes multiple battery boxes removably positioned in the cabinet housing, and each battery box includes at least one battery. Each battery box is vented through a distinct one of the multiple vents of the cabinet housing to inhibit hydrogen gas from escaping said battery box into the at least one equipment chamber.

According to yet another aspect of the present disclosure, a method of exchanging components in a telecommunications equipment cabinet is disclosed. The telecommunications cabinet includes at least one equipment chamber defined within the cabinet housing and multiple battery boxes positioned in the cabinet housing. The at least one equipment chamber has one or more electrical components disposed therein. Each battery box includes at least one battery and is isolated from the at least one equipment chamber to inhibit hydrogen gas from escaping the battery box into the at least one equipment chamber. The method includes removing one of the multiple battery boxes from the cabinet housing to define a space previously occupied by said one of the multiple battery boxes, and inserting another electrical component into the space previously occupied by said one of the multiple battery boxes while maintaining isolation between the inserted electrical component and the other battery box(es) remaining in the cabinet housing to inhibit hydrogen gas from escaping the other battery box(es) to the inserted electrical component.

Further aspects and areas of applicability will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure

### DRAWINGS

The drawings described herein are for illustrative purposes only of selected embodiments and not all possible implementations, and are not intended to limit the scope of the present disclosure.

FIG. 1 is a block diagram of a perspective view of a telecommunications equipment cabinet, according to one example embodiment of the present disclosure.

FIG. 2 is a perspective view of the telecommunications equipment cabinet of FIG. 1, with a cabinet door in an open position.

FIG. 3 is a perspective view of a telecommunications equipment cabinet including an air conditioner, according to another example embodiment of the present disclosure.

FIG. 4 is a perspective view of the telecommunications equipment cabinet of FIG. 3, with a cabinet door in an open position.

FIG. 5 is a front isometric exploded view of a battery box assembly of the telecommunications equipment cabinet of FIG. 2.

FIG. 6 is a front isometric exploded view of the battery box assembly of FIG. 5, including additional components.

FIG. 7 is a rear isometric view of the battery box assembly of FIG. 5.

FIG. 8 is a front isometric view of the battery box assembly of FIG. 5.

FIG. 9 is an enlarged view of a portion of the telecommunications equipment cabinet of FIG. 2.

FIG. 10 is a front isometric exploded view of the battery box assembly of FIG. 5, including floor reinforcement brackets.

FIG. 11 is a bottom isometric view of the battery box assembly of FIG. 5, including a strip gasket.

FIG. 12 is an enlarged view of a portion of the telecommunications equipment cabinet of FIG. 2.

FIG. 13 is an enlarged view of a portion of the telecommunications equipment cabinet of FIG. 4.

FIG. 14 is an exploded enlarged view of a portion of the telecommunications equipment cabinet of FIG. 2.

FIG. 15 is an exploded enlarged view of a portion of the telecommunications equipment cabinet of FIG. 4.

FIG. 16 is a perspective view of the telecommunications equipment cabinet of FIG. 4 including two battery box assemblies having SAFT batteries.

FIG. 17 is a perspective view of the telecommunications equipment cabinet of FIG. 2 including two battery box assemblies having VRLA batteries.

Corresponding reference numerals indicate corresponding features throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

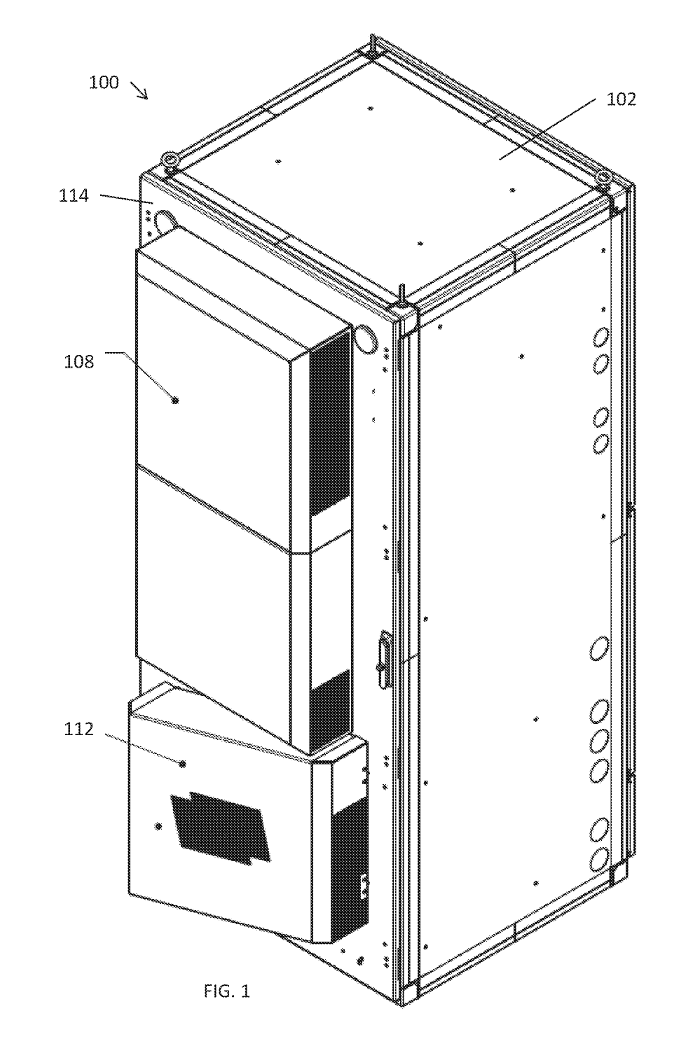

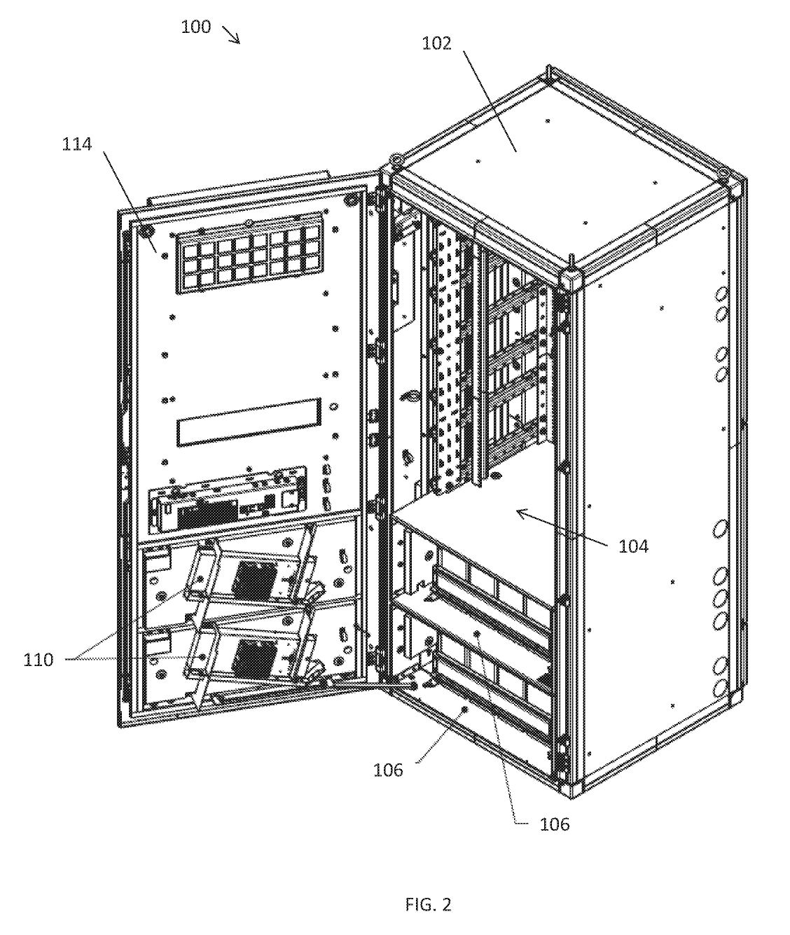

A telecommunications equipment cabinet according to one example embodiment of the present disclosure is illustrated in FIGS. 1 and 2, and indicated generally by reference number 100. As shown in FIGS. 1 and 2, the telecommunications equipment cabinet 100 includes a cabinet housing 102 and at least one equipment chamber 104 defined within the cabinet housing 102. One or more electrical components (not shown) are disposed within the equipment chamber 104.

The equipment cabinet 100 includes two battery boxes 106 (e.g., battery box assemblies) removably positioned in the cabinet housing 102. Each battery box 106 includes at least one battery. Each battery box 106 is isolated from the equipment chamber 104 to inhibit hydrogen gas from escaping the battery box 106 into the equipment chamber 104. Although FIG. 2 illustrates two battery boxes 106, other embodiments may include more or less battery boxes 106.

As described above, the telecommunications equipment cabinet 100 incorporates individual battery boxes 106 that are isolated from the equipment chamber 104, and are removable. This allows a user to separate (e.g., isolate) the equipment chamber 104 of the telecommunications equipment cabinet 100 from the batteries inside the battery boxes 106 to reduce (e.g., eliminate) a risk of potential hydrogen outgassing issues from the batteries. For example, dangerous hazards can arise when batteries outgas hydrogen into the equipment chamber 104 of the telecommunications equipment cabinet 100.

The telecommunications equipment cabinet 100 also allows the battery boxes 106 to be removed if the user desires to place electrical component(s) in a space previously occupied by a removed battery box, to expand the electrical component capacity of the telecommunications equipment cabinet 100, etc. For example, use of removable battery boxes 106 (e.g., as opposed to permanent members of the telecommunications equipment cabinet 100), allows a user to replace a battery box 106 with additional equipment in that space if desired. In this manner, the removable battery boxes 106 can allow for equipment expansion in the event multiple battery strings are deemed unnecessary, etc. A user can increase (e.g., optimize) deployment space available in the telecommunications equipment cabinet, which can reduce long term costs.

The telecommunications equipment cabinet 100 includes a combination heat exchanger 108 and thermoelectric cooler (TEC) 110 cooling system. The heat exchanger 108 is configured to provide sufficient thermal cooling to cool electronic components in the equipment chamber 104 of the telecommunications equipment cabinet 100.

TECs 110 within a TEC shroud 112 of the telecommunications equipment cabinet 100 are configured to provide sufficient thermal cooling for the battery boxes 106. As shown in FIG. 1, the heat exchanger 108, TECs 110 and TEC shroud 112 are positioned on a cabinet door 114 (e.g., cabinet door assembly) of the telecommunications equipment cabinet 100.

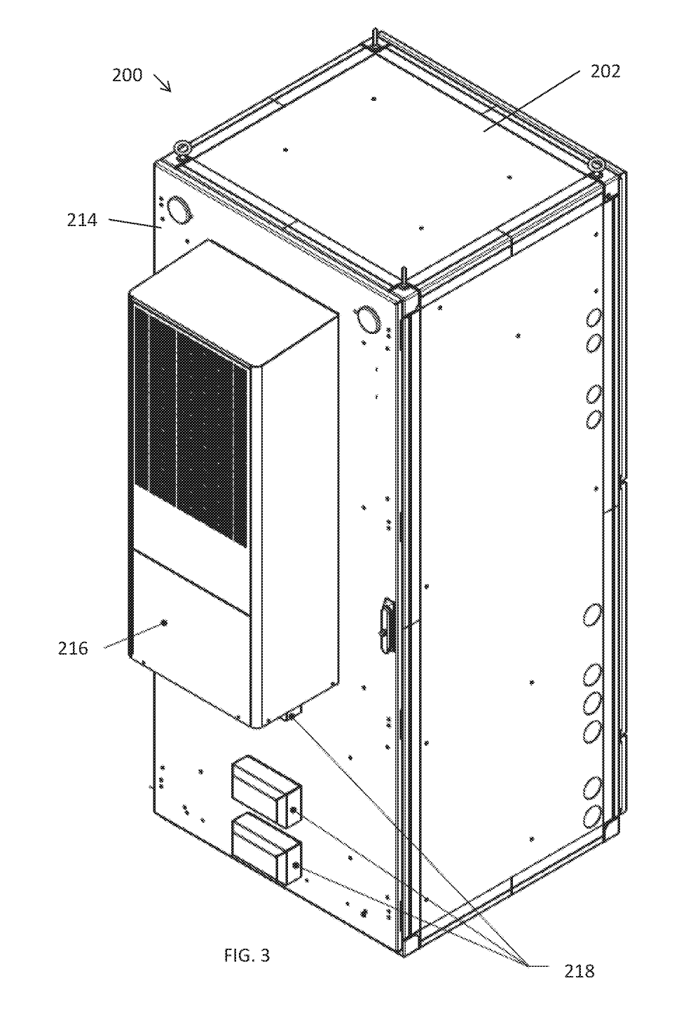

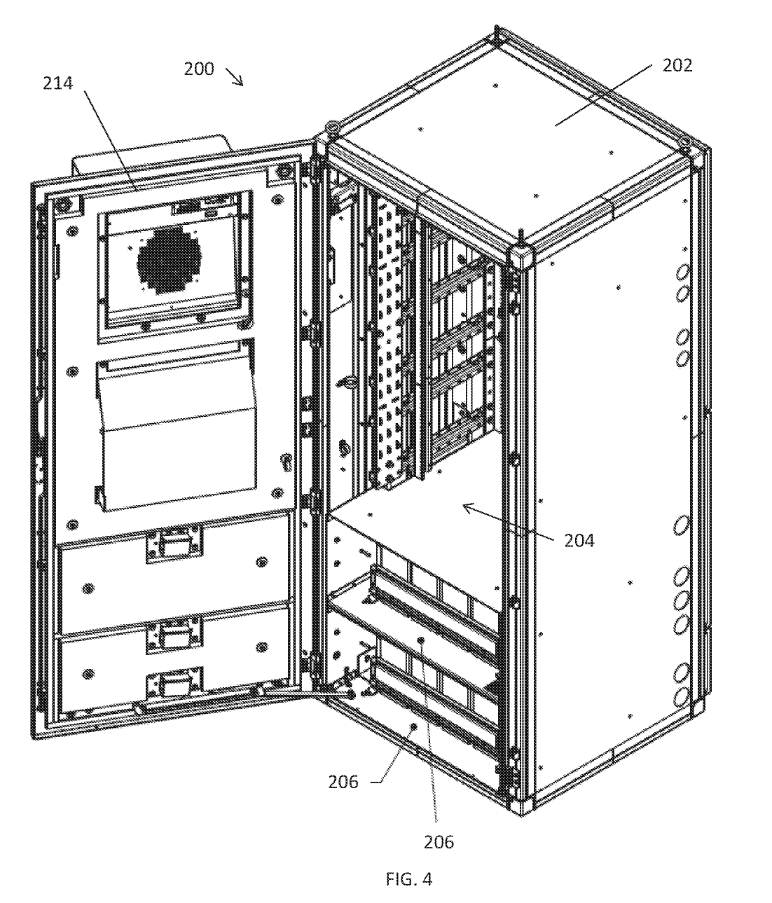

FIGS. 3 and 4 illustrate a telecommunications equipment cabinet 200 according to another example embodiment of the present disclosure. The telecommunications equipment cabinet 200 is similar to the telecommunications equipment cabinet 100 of FIGS. 1 and 2, but includes a cooling system having an air conditioner 216 and vent shrouds 218 instead of the heat exchanger 108, TECs 110 and the TEC shroud 112.

The air conditioner 216 and vent shrouds 218 are positioned on a cabinet door 214, which is coupled to cabinet housing 202. The telecommunications equipment cabinet 200 includes an equipment chamber 204, and two battery boxes 206.

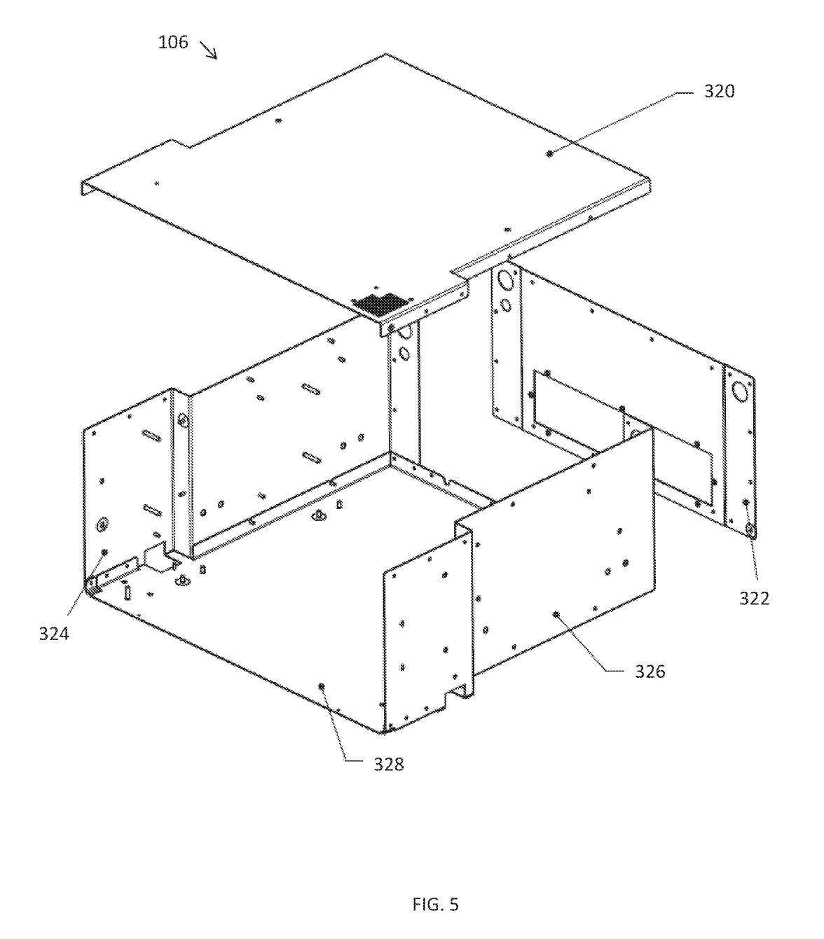

As shown in FIG. 5, the battery boxes 106 include a top panel 320, a back wall 322, a left wall 324, a right wall 326, and a floor panel 328. The panels 320 and 328, and the walls 322, 324 and 326, may be formed of steel (e.g., sixteen gauge painted steel) components that are riveted and bolted together.

In other embodiments the panels 320 and 328, and the walls 322, 324 and 326, may be formed of other suitable materials (e.g., plastic), and may be coupled together using other suitable fastening approaches. For example, the panels 320 and 328, and the walls 322, 324 and 326, may be welded together, may be die-cast as a one-piece box, etc. Gaps and seams in the panels 320 and 328, and the walls 322, 324 and 326, can be sealed with an adhesive silicone (e.g., to form an air-tight seal).

The battery box 106 may include side restraint brackets 330 to align and restrain one or more batteries in the battery box 106. For example, each battery box 106 may include one or more batteries in any suitable configuration, such as a string of four valve-regulated lead-acid (VRLA) batteries, one SAFT battery, etc. In the case of a string of four VRLA batteries, the side restraint brackets 330 may be adapted to restrain the outer two VRLA batteries.

The battery box 106 can include a removable sealed access panel assembly 332 at the rear of the battery box 106, which allows a user to open the battery box 106 if necessary. In some embodiments, the rear of the telecommunications equipment cabinet 100 may also provide rear access to a user (e.g., to access a battery box 106 inside the telecommunications equipment cabinet 100). The access panel assembly 332 includes a stop bracket 334 that sets a depth of batteries in the battery box 106.

In the case of a string of VRLA batteries, the access panel assembly 332 may also include restraint brackets 336 (e.g., “in-between” restraint brackets) for use with the VRLA string of batteries. A front brace assembly 338 can also include restraint brackets 336 for use with a string of VRLA batteries. The restraint brackets 336 may be removed in embodiments that include only one battery (e.g., one SAFT battery), etc.

In some embodiments, the front brace assembly 338 can mount to forward side restraint brackets 330. The forward side restraint brackets 330 may be adjustable in their depth position. This can allow for accommodation of different battery depths.

The battery box 106 may include a circuit breaker bracket 340. The circuit breaker bracket 340 can mount any suitable circuit breaker as specified by a user (e.g., a 250 Amp F series circuit breaker, etc.), to provide desired battery protection. The circuit breaker bracket 340 can include switch guards to inhibit accidental tripping of the circuit breaker.

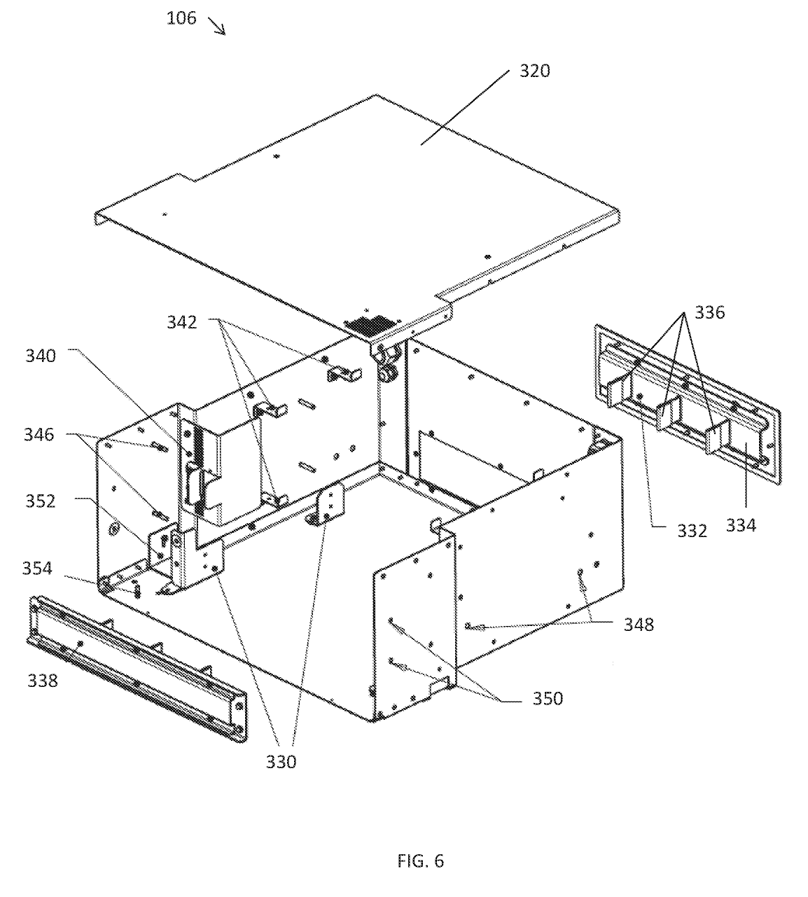

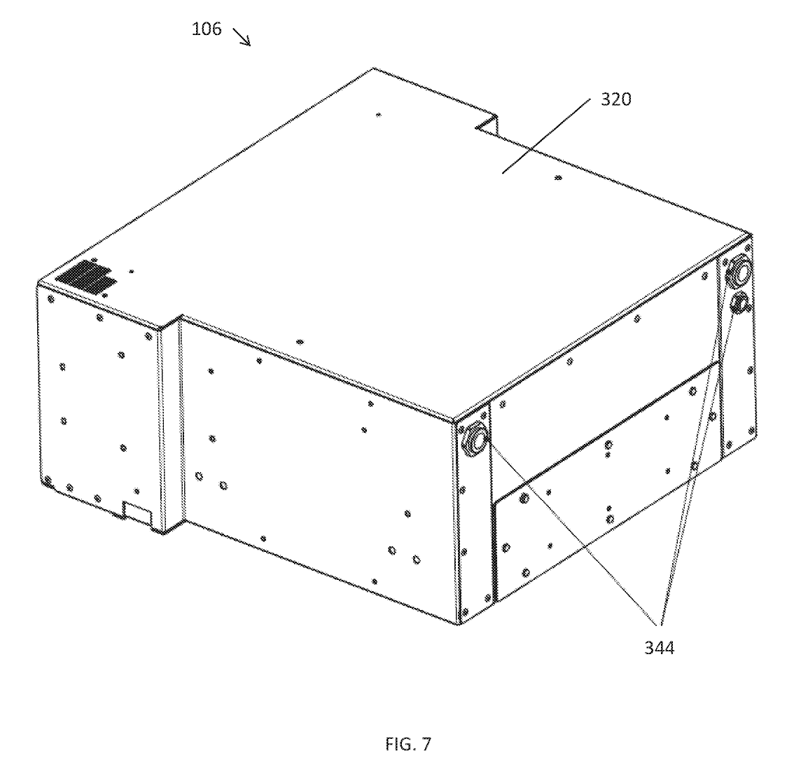

As shown in FIGS. 6 and 7, the battery box 106 can include cable management brackets 342 and exit ports 344 for routing cables (e.g., battery cables, circuit breaker cables, etc.), out of the battery box 106. The exit ports 344 may include industry standard liquid-tight-fittings (LTFs) sized to fit the cables exiting the battery box 106. In the event the LTFs do not fully seal the exit port opening, adhesive silicone may be used to complete the seal.

The battery box 106 may include any suitable fasters for coupling the battery box 106 to the telecommunications equipment cabinet 100, including but not limited to insulation studs 346, internal frame mounting features 348, external frame mounting features 350, a cabinet mounting access panel 352, a wind latch stud 354, etc.

These mounting features can allow for mounting the battery box 106 to internal and/or external frames of the telecommunications equipment cabinet 100 (e.g., using machine bolts, etc.). Mounting of the battery box 106 to the telecommunications equipment cabinet 100 can improve the rigidity and structural integrity of the telecommunications equipment cabinet 100, and the use of optional machine bolts allows for the battery box 106 to be disassembled from the telecommunications equipment cabinet 100.

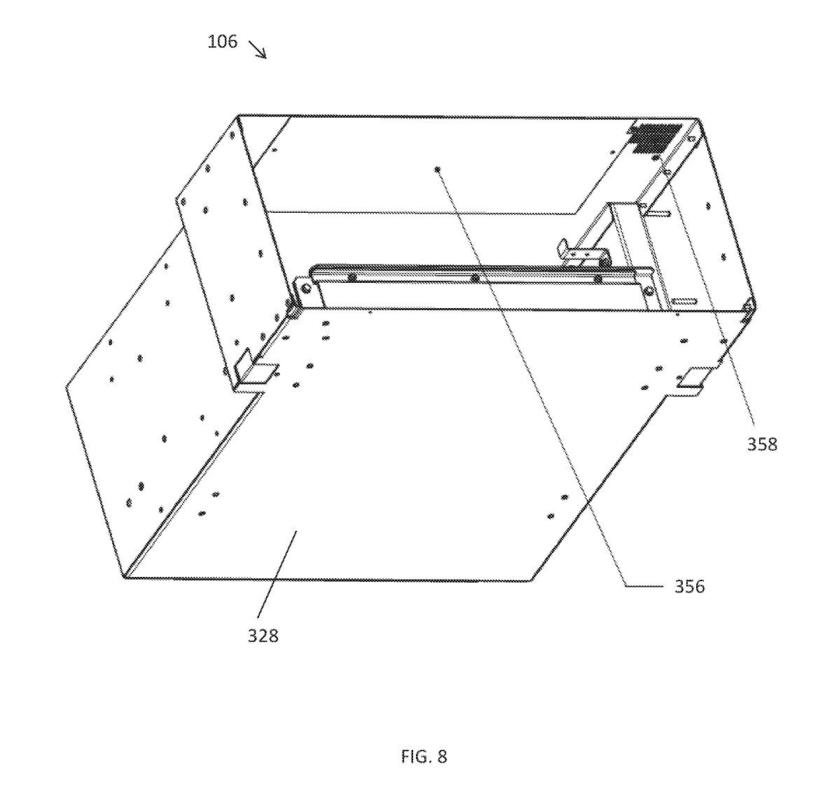

Referring back to FIG. 8, a NOMEX material 356 (e.g., a flame-resistant meta-aramid polymer material), may be affixed (e.g., via rivets) to an inside roof of the battery box 106 to inhibit (e.g., prevent) battery posts from coming in direct contact with sheet metal of the roof of the battery box 106.

The roof of the battery box 106 may include one or more perforations 358. The perforation(s) 358 can allow airflow between multiple battery boxes 106. The perforation(s) 358 may be used to facilitate removal of hydrogen gas from multiple battery boxes 106, to transfer heat out of multiple battery boxes 106, etc. If more battery boxes 106 are desired, additional perforations 358 can be included between each battery box 106.

In other embodiments, multiple battery boxes 106 may not include any perforation(s) 358. In that case, each of the multiple battery boxes 106 may be isolated from each other battery box 106 to inhibit hydrogen gas from moving between multiple battery boxes 106, to inhibit hydrogen gas escaping to the equipment chamber 104 if one of the multiple battery boxes 106 is removed from the telecommunications equipment cabinet 100, etc.

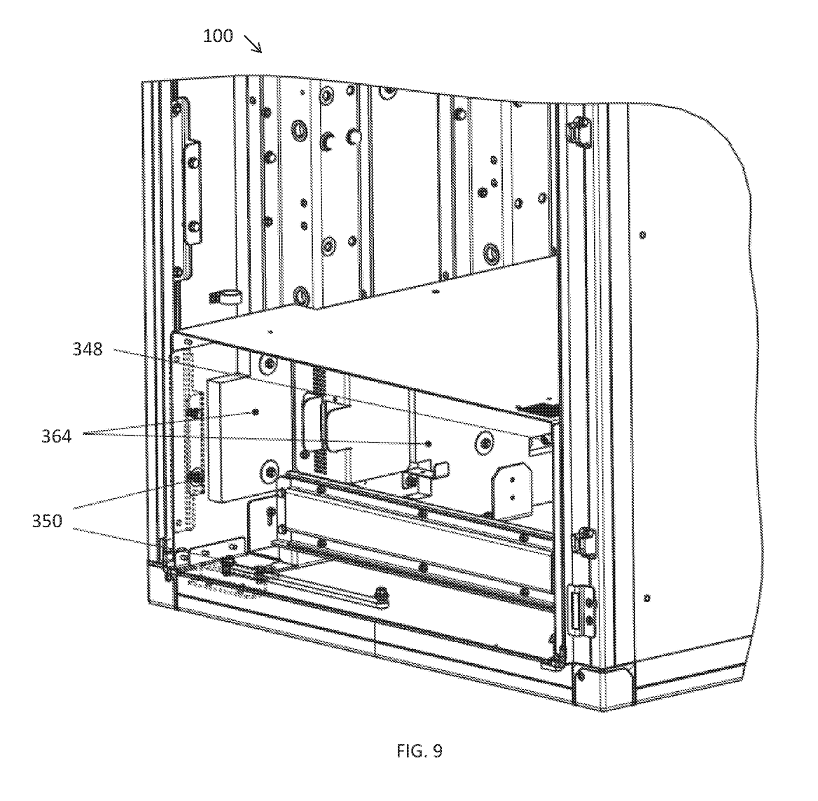

As shown in FIGS. 6 and 9, a lower battery box 106 can be assembled onto internal and/or external frames of the telecommunications equipment cabinet 100. The lower battery box 106 includes a mounting stud 354 for a door wind resistant bracket, and access panels 352 for providing access to locations where the telecommunications equipment cabinet 100 can be assembled to a concrete pad, installation frame, etc.

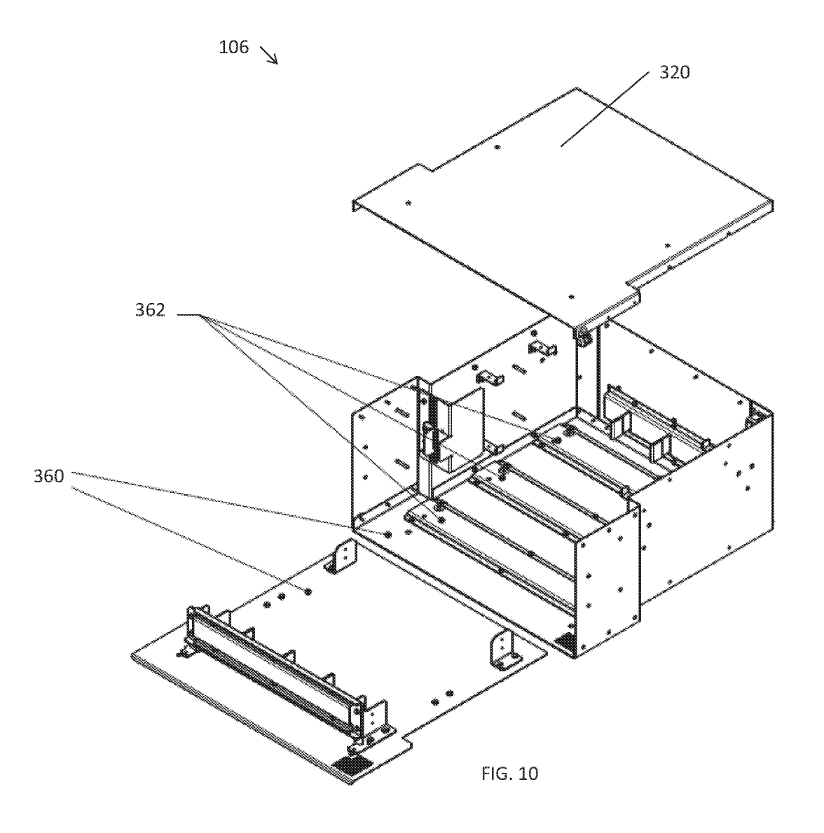

As shown in FIGS. 9 and 10, the upper battery box 106 can also assemble to internal and/or external frames of the telecommunications equipment cabinet 100, and can incorporate a double floor 360 with reinforcement brackets 362 to support the batteries inside the battery box 106.

In some embodiments, the battery box 106 may include mounting features for thermal insulation. For example, FIG. 9 illustrates thermal insulation 364 positioned along the battery boxes 106. Thermal insulation along the battery box 106 may be more desirable when a combination heat exchanger 108 and TEC 110 cooling system is used with the telecommunications equipment cabinet 100, but less necessary when an air conditioner 216 cooling system is used with the telecommunications equipment cabinet 100.

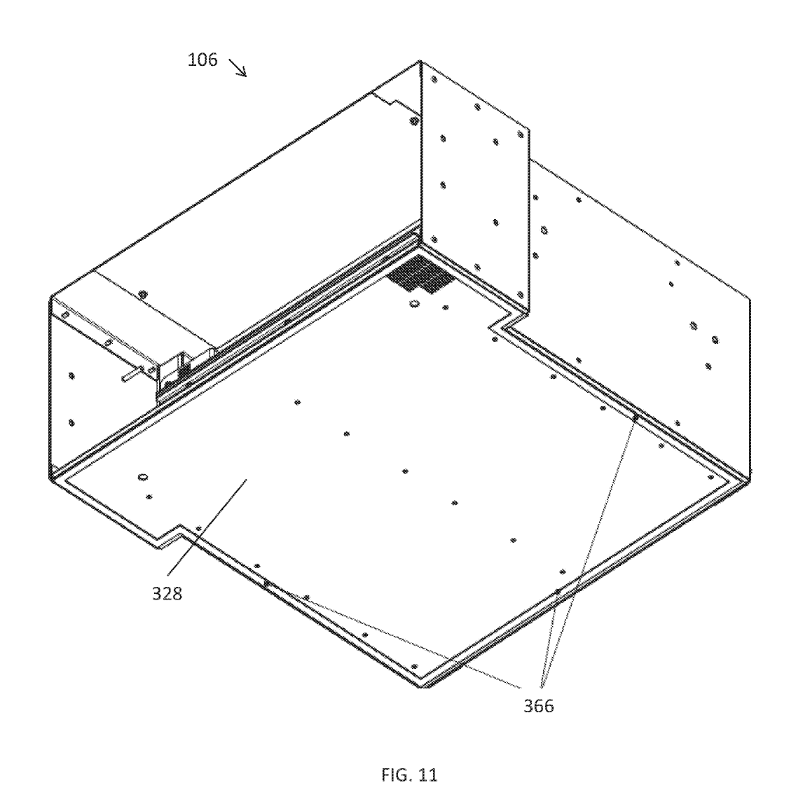

FIG. 11 illustrates an adhesive strip gasket 366 along the bottom panel 328 (e.g., a bottom surface) of the battery box 106. The adhesive strip gasket can facilitate assembly of two battery boxes 106 to one another, provide a seal between two battery boxes 106, etc.

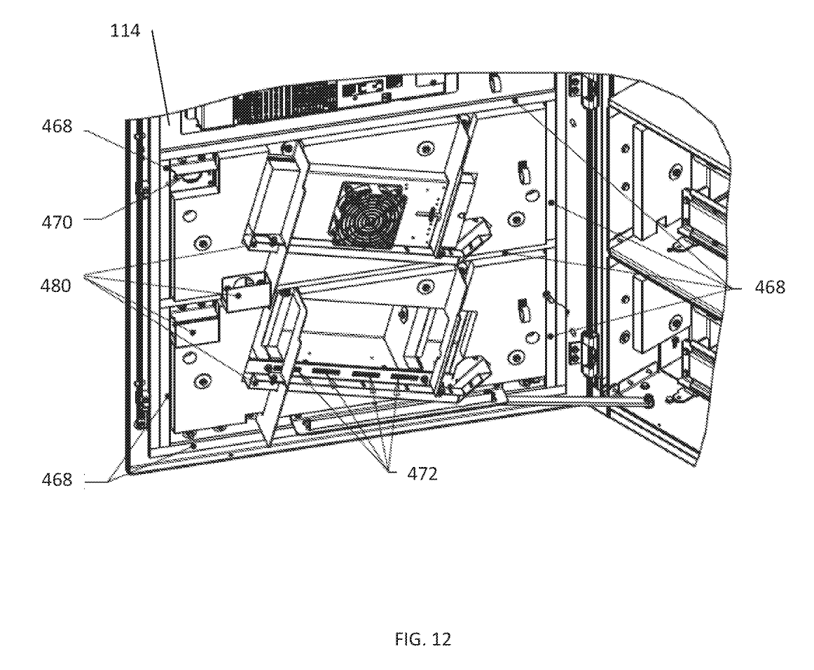

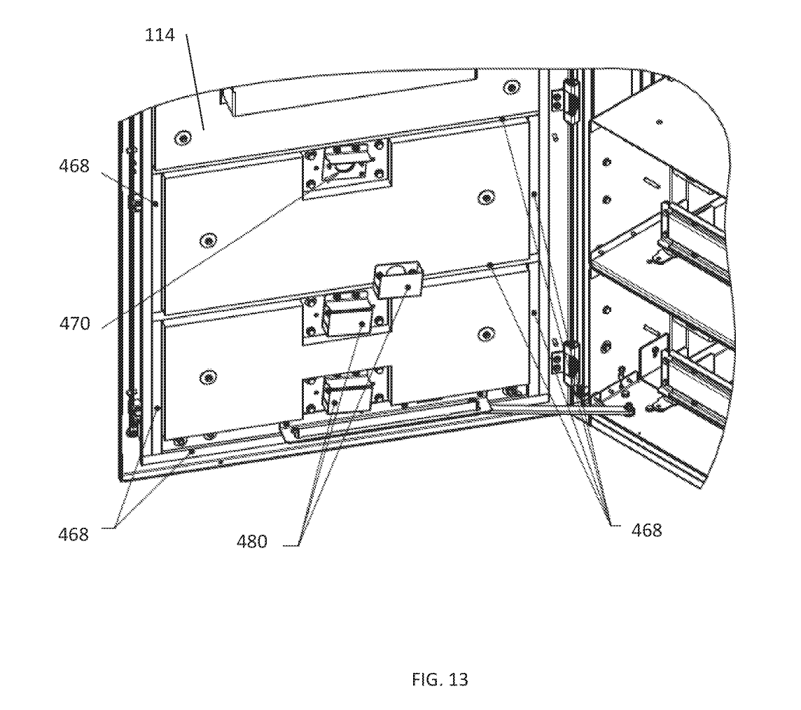

The cabinet door 114 may include features that supplement (e.g., complete) isolation of the battery boxes 106 from the equipment chamber 104, and provide an airflow (e.g., venting) rate sufficient to meet hydrogen outgassing requirements. As shown in FIGS. 12 and 13, an adhesive strip gasket 468 may be placed on an inside surface of the cabinet door 114, to align with a perimeter of an opening of each battery box 106. The adhesive strip gasket 468 may be also be used to seal the cabinet door 114.

Although FIGS. 12 and 13 illustrate an adhesive strip gasket 468 placed on an inside surface of the cabinet door 114 to align with a perimeter of an opening of each battery box 106, other embodiments may not include an adhesive strip gasket 468 on the cabinet door 114. In those cases, the cabinet door 114 may directly contact the perimeter of an opening of each battery box 106 to facilitate isolation of each battery box 106 from the equipment chamber 104.

In other embodiments, the openings of the battery boxes 106 may contact a surface of the cabinet housing 102 other than the door. For example, openings of the battery boxes 106 may contact side walls, rear walls, etc. of the cabinet housing 102 to facilitate isolation of each battery box 106 from the equipment chamber 104.

Referring again to FIGS. 12 and 13, when the battery boxes 106 are assembled in the telecommunications equipment cabinet 100, the battery boxes 106 may have their front edges in alignment with the lead edges of the external frame of the telecommunications equipment cabinet 100. When the cabinet door 114 is closed, the front edges of the battery boxes 106 can interface with the strip gasket 468 to effectively isolate (e.g., seal) the battery boxes 106 from the rest of the telecommunications equipment cabinet 100.

As shown in FIGS. 12 and 13, an open area ventilation design is utilized to address the battery hydrogen outgassing requirement. Specifically, open area vents 470 are spaced apart from one another (e.g., as far apart vertically as possible). In some embodiments, a minimum open area size for each open area vent 470 may optionally be about a 1.375 inch diameter circle.

In the telecommunications equipment cabinet 100 including the heat exchanger 108 and TEC 110 cooling system, a lowest open area vent 470 may be positioned directly under the lower TEC 110 via rectangular slots 472 that exceed the required open area. Additional open area vents 470 can be positioned at higher (e.g., highest) points within the perimeters of the openings of the battery boxes 106. Similar open area vent configurations can be used on the telecommunications equipment cabinet 200 including the air conditioner 216 cooling system.

Although FIGS. 12 and 13 illustrate the vents 470 positioned on the cabinet door 114, other embodiments may include vents positioned on other surfaces of the cabinet housing 102. For example, vents may be positioned on a side wall of the cabinet housing 102, a rear wall of the cabinet housing 102, top or bottom panels of the cabinet housing 102, etc.

The location of the vents can correspond to an orientation of battery boxes 106. For example, if the battery boxes 106 have openings contacting a side wall of the cabinet housing 102, the side wall of the cabinet housing 102 may include vents for venting hydrogen gas from the openings of the battery boxes 106. In some cases, each battery box 106 may correspond to a distinct vent, to facilitate isolation of each battery box 106 from the other battery boxes 106 and the equipment chamber 104.

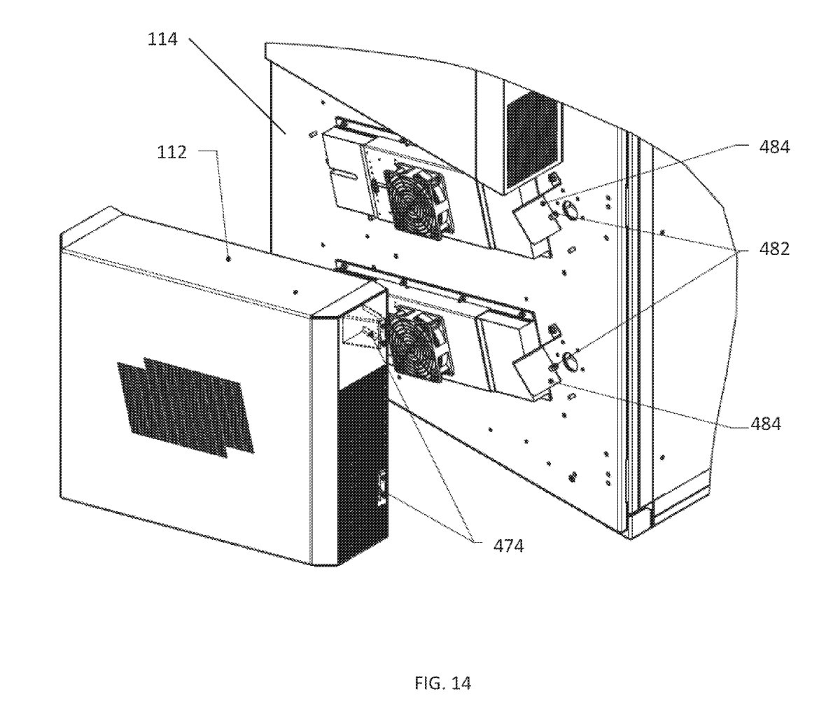

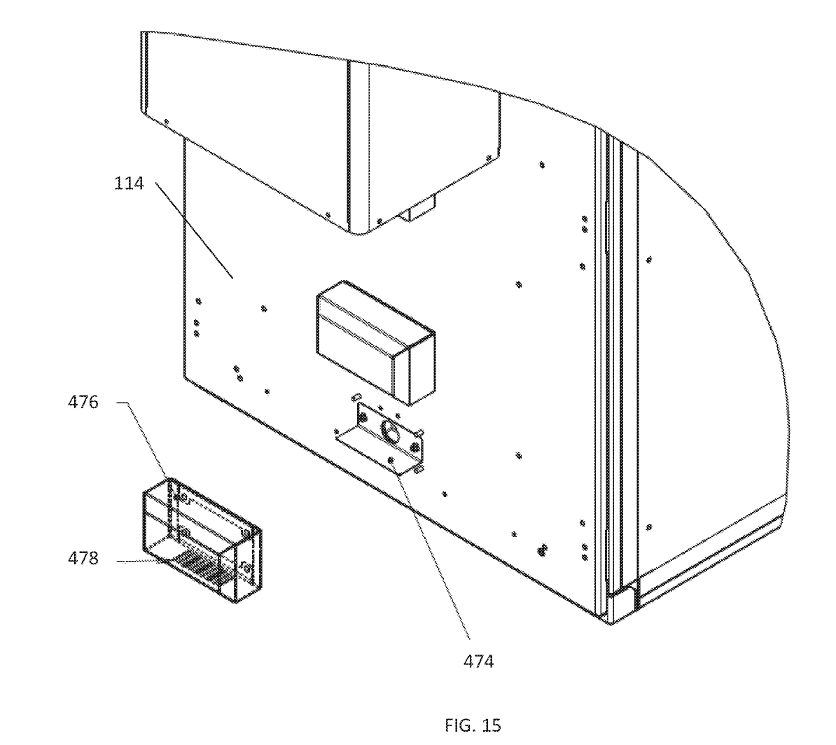

In order to protect the telecommunications equipment cabinet 100 from unwanted water entry, the open area vents 470 can be positioned on an external side of the cabinet door 114 by water guards including plates 474 and/or shrouds 476, that cover the open area vents 470 as shown in FIGS. 14 and 15. In some embodiments, the shrouds 476 on the outside of the cabinet door 114 may include perforations 478 to allow for airflow into the battery boxes 106.

On the inside of the cabinet door 114, drip pans 480 may be used to catch any water that enters through the open area vents 470. The drip pans 480 may then drain the water back out of the front of the cabinet door 114 via drip tubes 482 that are incorporated into the drip pans 480.

On an external side of the cabinet door 114, angled air deflector plates 484 may be used utilized to direct warm return air from the TECs 110 away from the open area vents 470. This inhibits (e.g., prevents) the warm return air from the TECs 110 from entering the telecommunications equipment cabinet 100.

The battery boxes 106 can be designed work with both heat exchanger/TEC (HEX/TEC) cooling systems and air conditioner cooling systems, which can make the base cabinet (e.g., the telecommunications equipment cabinet 100 not including the cabinet door 114) essentially independent of the cooling system the end user decides to use. For example, different cabinet doors 114 may incorporate either a heat exchanger/TEC cooling system or an air conditioner system, and either cabinet door 114 could be used with the same base cabinet. This can help manage cabinet configuration requirements, reduce part number management, improve overall manufacturability of the telecommunications equipment cabinets, etc.

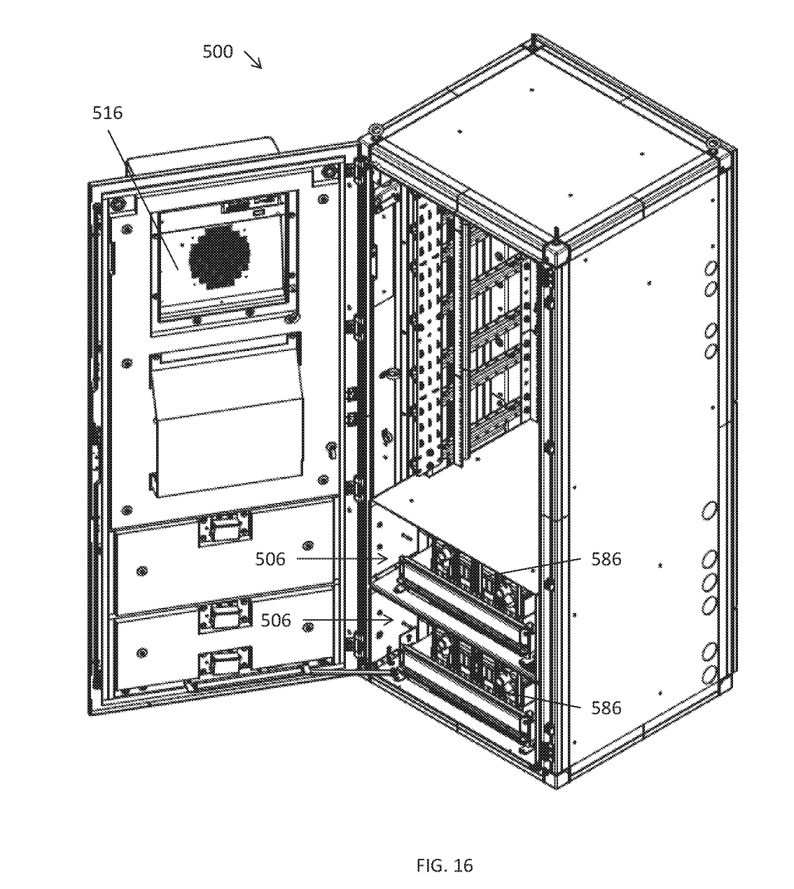

FIG. 16 illustrates an example embodiment of a telecommunications equipment cabinet 500 including an air conditioning cooling system 516 and two battery boxes 506. Each battery box 506 houses one SAFT battery 586.

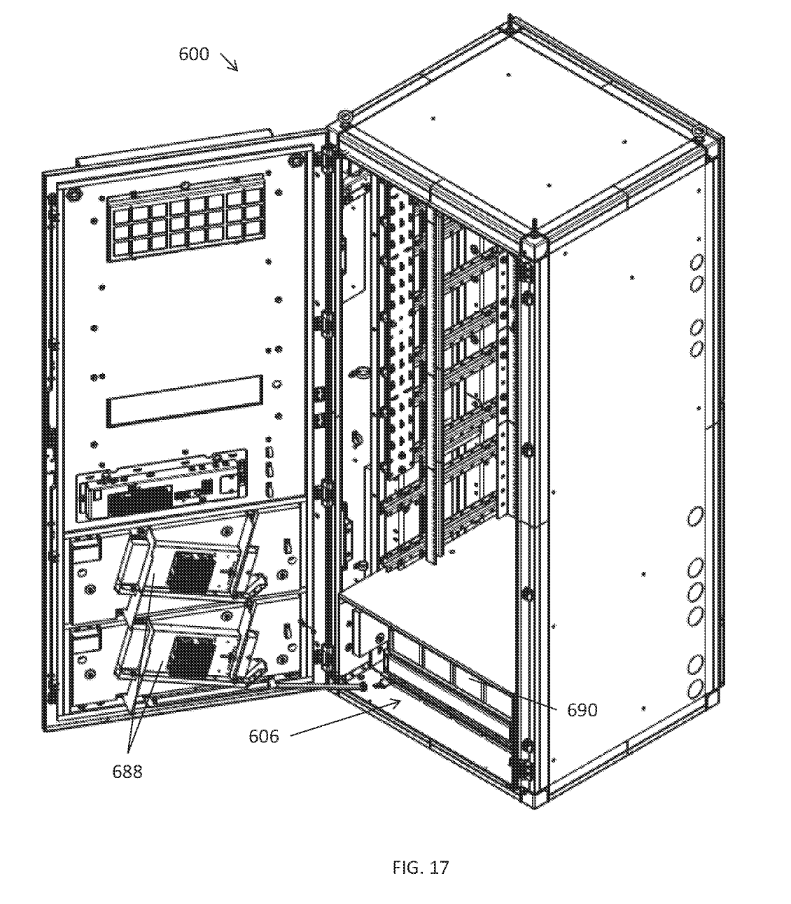

FIG. 17 illustrates an example embodiment of a telecommunications equipment cabinet 600 including a HEX/TEC cooling system 688 and one battery box 606. The battery box 606 houses a string of VRLA batteries 690.

The telecommunications equipment cabinets described herein may be used in any suitable applications, such as telecommunications network electrical equipment cabinets, etc. The telecommunications equipment cabinets may have any suitable size (e.g., about 84 inches, etc.).

According to another example embodiment, a telecommunications equipment cabinet includes a cabinet housing having multiple vents, and at least one equipment chamber defined within the cabinet housing. The at least one equipment chamber has one or more electrical components disposed therein.

The telecommunications equipment cabinet also includes multiple battery boxes removably positioned in the cabinet housing, and each battery box includes at least one battery. Each battery box is vented through a distinct one of the multiple vents of the cabinet housing to inhibit hydrogen gas from escaping said battery box into the at least one equipment chamber.

Each vent may be positioned within the perimeter of the opening of the corresponding battery box from which the vent passes hydrogen gas. The cabinet housing may include a strip gasket corresponding to the perimeter of the opening of the battery box to seal the perimeter of the opening of the battery box.

In some embodiments, the cabinet housing includes a cabinet door, and the cabinet door contacts the perimeter of the opening when the cabinet door is in a closed position. The battery box may include multiple walls that are riveted or bolted together with seams between the multiple walls sealed with an adhesive silicone, the battery box may include multiple walls that are welded together, the battery box may include a one-piece die-cast box, etc.

According to another example embodiment, a method of exchanging components in a telecommunications equipment cabinet is disclosed. The telecommunications cabinet includes at least one equipment chamber defined within the cabinet housing and multiple battery boxes positioned in the cabinet housing. The at least one equipment chamber has one or more electrical components disposed therein. Each battery box includes at least one battery and is isolated from the at least one equipment chamber to inhibit hydrogen gas from escaping the battery box into the at least one equipment chamber.

The method includes removing one of the multiple battery boxes from the cabinet housing to define a space previously occupied by said one of the multiple battery boxes, and inserting another electrical component into the space previously occupied by said one of the multiple battery boxes while maintaining isolation between the inserted electrical component and the other battery box(es) remaining in the cabinet housing to inhibit hydrogen gas from escaping the other battery box(es) to the inserted electrical component.

In some embodiments, removing one of the multiple battery boxes includes removing one of the multiple battery boxes from the cabinet housing without moving any of the one or more electrical components disposed in the at least one equipment chamber. The cabinet housing may include an internal frame or an external frame. In those cases, removing one of the multiple battery boxes can include removing machine bolts to decouple said one of the multiple battery boxes from the internal frame or the external frame.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A telecommunications equipment cabinet comprising:
a cabinet housing;
at least one equipment chamber defined within the cabinet housing, the at least one equipment chamber having one or more electrical components disposed therein; and
a battery box removably positioned in the cabinet housing, the battery box including at least one battery, the battery box isolated from the at least one equipment chamber to inhibit hydrogen gas from escaping the battery box into the at least one equipment chamber.

2. The telecommunications electrical equipment cabinet of claim 1, wherein the battery box is a first battery box, the equipment cabinet further comprising a second battery box, the second battery box removably positioned in the cabinet housing and isolated from the equipment chamber to inhibit hydrogen gas from escaping the battery box into the at least one equipment chamber.

3. The telecommunications equipment cabinet of claim 2, wherein the first battery box and the second battery box each define one or more openings to allow air flow between the first battery box and the second battery box.

4. The telecommunications cabinet of claim 1, wherein:
the battery box defines an opening, the opening having a perimeter; and
the cabinet housing contacts the perimeter of the opening to facilitate isolation of the battery box from the at least one equipment chamber.

5. The telecommunications equipment cabinet of claim 4, wherein the cabinet housing includes a vent positioned within the perimeter of the opening of the battery box to vent hydrogen gas from the battery box.

6. The telecommunications equipment cabinet of claim 5, wherein the cabinet housing includes a water guard positioned adjacent the vent to inhibit water entry into the cabinet housing via the vent.

7. The telecommunications equipment cabinet of claim 5, further comprising:
a drip pan positioned to collect water that enters the cabinet housing through the vent; and
a drip tube connected with the drip pan to drain water collected by the drip pan out of the cabinet housing.

8. The telecommunications equipment cabinet of claim 4, wherein the cabinet housing includes a strip gasket corresponding to the perimeter of the opening of the battery box to seal the perimeter of the opening of the battery box.

9. The telecommunications equipment cabinet of claim 4, wherein:
the cabinet housing includes a cabinet door; and
the cabinet door contacts the perimeter of the opening when the cabinet door is in a closed position to facilitate isolation of the battery box from the at least one equipment chamber.

10. The telecommunications equipment cabinet of claim 1, wherein the battery box is removable from the cabinet housing without moving any of the one or more electrical components disposed in the at least one equipment chamber.

11. The telecommunications equipment cabinet of claim 1, wherein:
the cabinet housing includes an internal frame or an external frame; and
the battery box is removably coupled to the internal frame or the external frame via machine bolts.

12. The telecommunications equipment cabinet of claim 1, further comprising at last one of an air conditioner, a heat exchanger, and a thermoelectric cooler (TEC) positioned on the cabinet housing to reduce heat in the equipment chamber.

13. The telecommunications equipment cabinet of claim 1, wherein the one or more electrical components include telecommunications equipment.

14. The telecommunications equipment cabinet of claim 1, wherein the at least one battery includes a valve-regulated lead-acid (VRLA) battery or a SAFT battery.

15. The telecommunications equipment cabinet of claim 1, wherein:
the battery box includes multiple walls that are riveted or bolted together; and
seams between the multiple walls are sealed with an adhesive silicone.

16. The telecommunications equipment cabinet of claim 1, wherein the battery box includes multiple walls that are welded together.

17. The telecommunications equipment cabinet of claim 1, wherein the battery box includes a one-piece die-cast box.

18. A telecommunications equipment cabinet comprising:
a cabinet housing having multiple vents;
at least one equipment chamber defined within the cabinet housing, the at least one equipment chamber having one or more electrical components disposed therein; and
multiple battery boxes removably positioned in the cabinet housing, each battery box including at least one battery, each battery box vented through a distinct one of the multiple vents of the cabinet housing to inhibit hydrogen gas from escaping said battery box into the at least one equipment chamber.

19. The telecommunications cabinet of claim 18, wherein:
each battery box defines an opening, the opening having a perimeter; and
the cabinet housing contacts the perimeters of the openings of each battery box to facilitate isolation of the battery boxes from the equipment chamber.

20. A method of exchanging components in a telecommunications equipment cabinet, the telecommunications cabinet including at least one equipment chamber defined within the cabinet housing and multiple battery boxes positioned in the cabinet housing, the at least one equipment chamber having one or more electrical components disposed therein, each battery box including at least one battery, each battery box isolated from the at least one equipment chamber to inhibit hydrogen gas from escaping the battery box into the at least one equipment chamber, the method comprising:
removing one of the multiple battery boxes from the cabinet housing to define a space previously occupied by said one of the multiple battery boxes; and
inserting another electrical component into the space previously occupied by said one of the multiple battery boxes while maintaining isolation between the inserted electrical component and the other battery box(es) remaining in the cabinet housing to inhibit hydrogen gas from escaping the other battery box(es) to the inserted electrical component.

21-26. (canceled)
